(19) United States
(12) Patent Application Publication
(10) Pub. No.: US 2005/0284515 A1
(43) Pub. Date: Dec. 29, 2005

(54) Method for construction of rigid photovoltaic modules

(76) Inventors: Gary Don Stevens, Kitchener (CA); Milfred Dale Hammerbacher, Waterloo (CA); Glen Alexander Crossley, Hamilton (CA); Jonathan Daniel Albert, Philadelphia, PA (US)

Correspondence Address: BORDEN LADNER GERVAIS LLP, 1100-100 QUEEN ST, OTTAWA, ON, K1P 1J9, CA

(21) Appl. No.: 11/145,067

(22) Filed: Jun. 6, 2005

Related U.S. Application Data
(60) Provisional application No. 60/576,626, filed on Jun. 4, 2004.

(51) Int. Cl. H01L 25/00

(52) U.S. Cl. 136/251; 136/244

(57) ABSTRACT

A flexible solar module is provided sufficient rigidity for use in construction, and comparable rigidity to a glass based solar module, by incorporation of a metal backing to the module, preferably in the laminated module. The rigidity of the construction is enhanced by the inclusion of a corrugation, either in the metal backing, or in a structure that is affixed to the backing. The resulting structure is a modular unit that has connection points and does not need to be connected to other modules to operate. A connection point is provided by an integrated junction box that allows for a simpler installation and the use of standard building techniques for the installation on a roof or wall.

### CROSS REFERENCE TO RELATED APPLICATIONS

This application claims the benefit of priority of U.S. Provisional Patent Application No. 60/576,626 filed Jun. 4, 2004, which is incorporated herein by reference.

### FIELD OF THE INVENTION

The present invention relates generally to photovoltaic cells and modules thereof, such as solar cells and solar cell modules. More particularly, the present invention relates to structural stiffening of solar modules through geometric shaping, including corrugation.

### BACKGROUND OF THE INVENTION

Solar modules for generating electricity are well known in the art. The most common solar modules employ a glass superstrate that provides rigidity to the module, but also greatly increases the mass of the module and makes transportation difficult. To create a large solar module, the thickness of the glass is increased to provide sufficient strength to ensure the integrity of the module. If the glass is too thin, and does not provide sufficient rigidity, it can crack and the module will be useless.

Conventional photovoltaic modules can produce 200 W (with a surface area of approximately two square meters), but at such capacity their weight approaches 50 pounds. This weight limits the utility of these laminates for use in products that require simplified installation. This weight is mainly due to the requirement for thicker glass as surface area increases, in order to meet wind load requirements. Thinner glass is more susceptible to being fractured and is also susceptible to shear and torsion. A small fracture in the glass of a conventional solar module effectively renders the module useless, as the glass is typically safety glass and a small fracture will result in the rapid fracturing of the entire module. One skilled in the art will appreciate that substituting another material for glass in a conventional solar module is undesirable due to the characteristics of other transparent media.

Flexible solar modules are known in the field. These modules typically make use of thin film cells or cells using spherical silicon elements as the photovoltaic element, and are bonded between flexible superstrates and substrates by an encapsulant. These solar modules are, by their very nature, lighter weight than the conventional glass modules, but offer no support and cannot bear a load.

Flexible solar modules can typically be manufactured at a lower cost than glass photovoltaic (PV) modules and offer many benefits related to portability and durability but cannot be incorporated as structural elements in construction as they cannot support a load.

By making flexible modules more rigid, they could be incorporated as structural elements in place of glass PV modules. This would allow a reduction in weight and allows for better scalability, as the mass per watt of generating capacity would not necessarily need to increase as it does with glass modules. Although using multiple smaller glass modules can often overcome the increase in the mass per waft, it increases the number of connections needed and amount of cable, which increases the overall cost and results in a more complex installation process.

Large glass PV modules also cause installation difficulties as the PV module adds to the weight of any pre-assembled component and thus requires heavy machinery to hoist modules onto roofs.

A mechanism to incorporate a rigid structure into flexible PV modules would address many of the downfalls of glass PV modules including the fragile nature of the modules, the Increased weight due to the thick glass, and the added installation difficulties.

Numerous pieces of prior art have been directed to creating standard roofing elements with integrated solar modules. A discussion of a sampling of the art is provided below.

U.S. Pat. No. 5,935,343 to Hollick teaches affixing solar cells to the top of a corrugate. The cells are Illustrated as being bolted to the top surface of the corrugate or affixed across the openings in the top surface. Hollick uses this configuration to allow air flow beneath the module to promote cooling. Hollick's teachings do not result in an integral unit, and would thus be difficult to implement using flexible modules, as the areas of the module not supported by the corrugate would not adequately bear wind loads. Above all, Hollick does not teach a method for constructing a stand alone module which can be rack mounted.

U.S. Pat. No. 6,201,179 to Dalacu discloses an array of modules installed on an interlocking corrugated support. The Dalacu reference also describes attaching modules to an interlocking corrugated roofing bed, using techniques similar to those taught by Hollick. As a result, the system taught in the Dalacu reference does not result in a stand alone module which can be rack mounted and in which system modules can be added or removed with ease.

U.S. Pat. No. 5,338,369 to Rawlings discloses an extruded corrugated core PV panel. The Rawlings reference describes an interlocking array of modules for use as an integrated roofing system. Though this system provides some structural integrity for the module, it requires the panels to be installed in an interlocking fashion, which can complicate installation and replacement of the modules. Additionally, as shown in FIG. 2, the modules are individually wired together at a combiner box, which is more complicated than simple inter-module connections. This adds to the installation complexity and cost.

U.S. Pat. No. 5,505,788 to Dinwoodie discloses a corrugated pan to hold phase change material against modules. As illustrated in the Dinwoodie reference, modules are simply affixed to the top of a corrugate or other structure, as a means of attachment to a horizontal surface. As a result, this approach would be required to use stand alone modules which have passed wind load requirements prior to attachment to said mounting structure.

U.S. Pat. No. 5,092,939 to Nath discloses PV cells laminated on a metal coil for field forming to make a standing seam roof construction. Significant shading of areas of the modules is likely on a seasonal basis, as the seams stand above the solar cell plane, creating reliability issues. Ease of replacement for individual modules is quite questionable for a system of this design.

U.S. Pat. No. 5,232,518 to Nath et al. discloses a roofing system similar to that disclosed in the '939 patent. The '518 patent teaches the interconnection of all installed modules so that a single connection to the module array is utilized. As noted above, shading and ease of module replacement are major issues with such designs.

U.S. Pat. No. 4,433,200 to Jester et al, discloses a roll formed pan on which conventional fragile silicon wafer-based cells are mounted. Without any internal reinforcement in this design, simply a frame around the perimeter, this approach fails to provide any improvement over glass superstrate designs as weight per area must significantly increase as module size increases, since much thicker substrates will be required to sustain wind load requirements. As a result, the approach taught by Jester is not suitable for large area modules.

U.S. Pat. No. 6,606,830 to Nagao et al is directed to reducing the number of connections to a house that a solar array requires. As disclosed in the Nagao reference, the PV modules are interlocking and they form a serial connection to each other. As such, individual modules are not easily replaced and also cannot withstand wind load requirements without first attachment to a roof deck.

U.S. Patent Application Publication No. 2002/0112419 to Dorr et al. is directed to affixing PV modules to a corrugate by use of an adhesive, and draws connecting cables from each individual module. That the specified corrugate structure is filled with insulating foam is a significant problem as inadequate dissipation of heat severely limits device performance. Additionally, this design suffers from shading by corrugate elements above the plane of the attached modules.

U.S. Pat. No. 6,498,289 to Mori et al. teaches a roofing element having a PV cell. A PV cell is attached to a backing whose sides are then bent into flanges. Elements are then added to the backing to space the structure from the roof. These spacers are then affixed to the roof, allowing for air ventilation behind the panel. Though bending the edges of the backing and affixing spacers provides support to the flexible PV panel, Mori admits that the panels cannot bear loads as the areas between spacers are not supported and thus can bend under loads.

One skilled in the art will appreciate that the interconnection of the solar modules as taught by many prior art references results in a large solar array that is physically interlocked. Should one of the modules fail most of this prior art does not provide for ease of replacement or removal from the circuit, to circumvent performance and reliability issues.

It Is, therefore, desirable to provide a supporting structure for flexible solar modules that provides rigidity and strength to allow the flexible solar module to bear loads for a variety of installation methods. It is also desirable to provide a modular structural element having a flexible solar panel capable of being removed or replaced with relative ease.

### SUMMARY OF THE INVENTION

It is an object of the present invention to obviate or mitigate at least one disadvantage of previous photovoltaic panel structured elements.

In a first aspect of the present invention there is provided a rigid solar module having a flexible solar module prelaminate. The module comprises a metal backing, a corrugated backing and a junction box. The metal backing is affixed to the prelaminate. Preferably, this provides a degree of rigidity to the prelaminate. The corrugated backing is affixed to the metal backing to provide rigidity to the combination of the metal backing and the prelaminate. The junction box is connected to the prelaminate, for transferring power to a load.

In an embodiment of the present invention, the metal backing is laminated to the prelaminate, and its edges are preferably folded over the edges of the corrugate backing to affix the corrugate backing to the metal backing. In another embodiment, a flexible backing is interposed between the metal backing and the prelaminate in a laminate. In a further embodiment, the corrugated backing and the metal backing are integral. In another embodiment, the edges of the corrugated backing are folded over the edges of the prelaminate to affix the corrugated backing to the metal backing. In a further embodiment, the junction box is positioned inside a trough in the corrugate.

In a second aspect of the present invention, there is provided a method of forming a rigid photovoltaic module from a flexible photovoltaic module. The method comprises the steps of affixing the flexible photovoltaic module to a rigid backing and structuring the rigid backed photovoltaic module to provide increased strength in at least one direction.

In embodiments of the second aspect of the present invention, the rigid backing is a metal backing, such as an aluminum backing. In another embodiment, the step of affixing can include at least one of gluing the flexible module to the backing, laminating the flexible photovoltaic module to the rigid backing, and integrally affixing the module to the backing.

In another embodiment, the step of structuring the metal backing Includes bending the rigid backed photovoltaic module to create a curve. This embodiment preferably includes adding supports in a hollow portion of the curve, connecting a junction box to the photovoltaic module and locating the junction box between supports in the hollow portion of the curve.

In a further embodiment, the step of structuring the metal backing includes corrugating the rigid backed photovoltaic module and affixing a junction box under a flat section of the corrugated rigid backed photovoltaic module.

In another embodiment, the step of structuring includes affixing the rigid backed photovoltaic module to a corrugate. This embodiment preferably includes folding the edges of one of the corrugate and the photovoltaic module over the edges of the other one of the corrugate and the photovoltaic module, connecting a junction box to the photovoltaic module and locating the junction box in a trough of the corrugate.

In a further embodiment, the step of structuring the metal backing includes bending the rigid backed photovoltaic module to create standing seams beneath the plane of the flexible photovoltaic module. This embodiment preferably includes connecting a junction box to the photovoltaic module and locating the junction box between two of the standing seams.

Other aspects and features of the present invention will become apparent to those ordinarily skilled in the art, upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 is a block diagram of a section of a flexible PV prelaminate of the present invention;

FIG. 2 is a block diagram of a section of a flexible PV cell of the present invention;

FIG. 3 is a block diagram of a section of a PV module of the present invention prior to being corrugated;

FIG. 4 is a block diagram of an open corrugated section of the PV module of FIG. 3;

FIG. 5 is a block diagram of an closed corrugated section of the PV module of FIG. 3;

FIG. 6 is a perspective view of a rigid PV module of the present invention attached to a corrugated backing;

FIG. 7 is a perspective view of the bottom of the assembly of FIG. 6;

FIG. 8 is a perspective view of a rigid PV module of the present invention formed to a curve;

FIG. 9 is a perspective view of the bottom of the assembly of FIG. 8;

FIG. 10 is a perspective view of corrugated backed modules of the present invention nesting;

FIG. 11 is a perspective view of an embodiment of the present invention;

FIG. 12 is a perspective view of a detail of the embodiment of FIG. 11;

FIG. 13 is a flowchart illustrating a method of the present invention;

FIG. 14 is a flowchart illustrating an embodiment of the method of FIG. 11;

FIG. 15 is a flowchart illustrating an embodiment of the method of FIG. 11; and

FIG. 16 is a flowchart illustrating an embodiment of the method of FIG. 11.

### DETAILED DESCRIPTION

Generally, the present invention provides a method and system for simplified installation of affordable and low weight photovoltaic (PV) modules that can be prepared in advance for modular installation. PV modules of the present invention use lower cost flexible laminates but can serve as replacements to conventional glass modules as they are rigid and have a planar surface much as glass PV modules do.

The present invention provides a flexible solar module that has sufficient structure and rigidity to be used in place of conventional glass superstrate photovoltaic (PV) modules. The flexible solar module can use either thin film PV cell-based panels or spherical silicon element-based panels. Those skilled In the art will appreciate the operation, manufacture and characteristics of these cells.

By eliminating the glass in conventional PV modules, it is possible to build products with areas of more than four square meters that do not exceed 50 pounds in weight. This allows for a reduction in overall production costs, as fewer parts have to be finished to produce the same equivalent energy. It also allows for a reduction in installation costs as fewer parts need to be installed. It is possible to install lighter modules using fewer construction workers and overhead cranes are not necessary. Although these designs are particularly useful for flexible PV modules, some of the designs disclosed below can be used with standard wafer technology when the backing designs have adequate rigidity to prevent cell breakage.

Most crystalline silicon wafer PV technologies use a glass superstrate and aluminum frame with a polymer backing film to encapsulate the solar cells, providing the needed moisture barrier and structural strength for stand alone modules. Flexible modules allow elimination of the weight of the glass cover by replacing it with a polymer film such as Ethylene/Tetrafluoroethylene Copolymer (ETFE). Although this eliminates the excessive weight of the glass, it is often necessary to provide a structural backing to support this flexible sandwich. Many materials that are used for building construction, truck trailer construction, and even signage are designed to be lightweight yet resist wind loading and uplift forces. The challenge is to find materials that are lighter than glass but do not significantly increase production costs. A number of designs which appear to meet these requirements have been found and their configuration as well as methods for construction will be detailed below as they apply to the present invention.

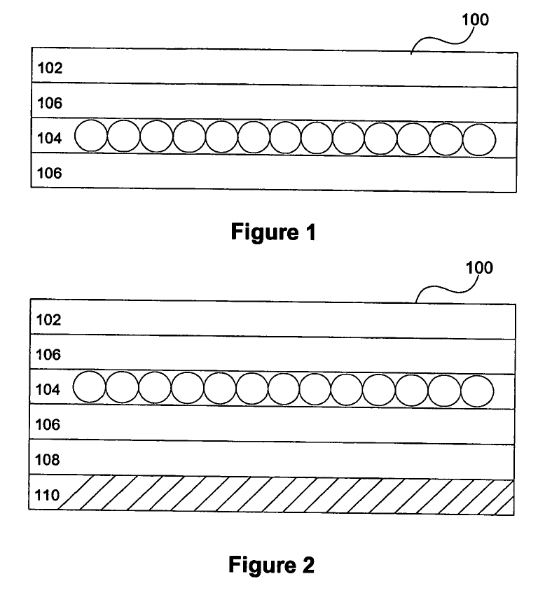

Typically a flexible solar module is composed of an array of cells. As illustrated in FIG. 1, each cell 100 is a sandwich of layers. A superstrate 102, typically ETFE, serves to protect a layer 104 of PV elements that function as PV diodes. This is the layer 104 that generates the electrical potential, it can be composed of silicon beads or a thin film of silicon or other semiconductor materials. The PV diode, or diodes, is typically encased in an encapsulent 106 that bonds the elements to the superstrate 102. As a product, at this point, the cell assembly can be referred to as a prelaminate as it has not yet been affixed to a substrate, but can be used to generate power.

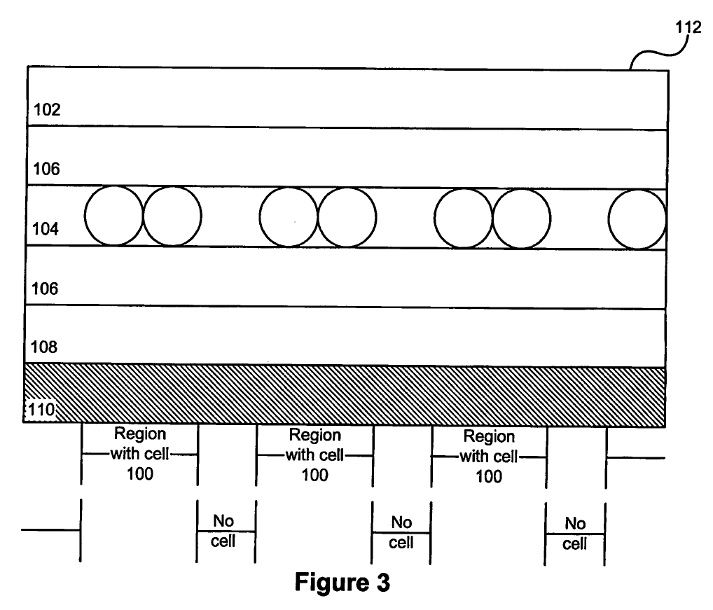

The prelaminate can be affixed to a substrate 108 such as a film or fiber backing, as shown in FIG. 2. This can then be affixed to a metal backing 110. The metal backing 110 is preferably included with the superstrate 102, the encapsulants 106 and the substrate 108 in a single step lamination process. In an alternate embodiment, a laminate is formed without the metal layer 110 and is then affixed to the metal layer 110. Contacts (not shown) from each cell 100 are connected to the other cells in the laminate as is common.

After creating an integral PV laminate on a backing, such as metal layer 110, the backing can then be given a structural form. The structural forming can include corrugating the backing to create either an open or a closed corrugate.

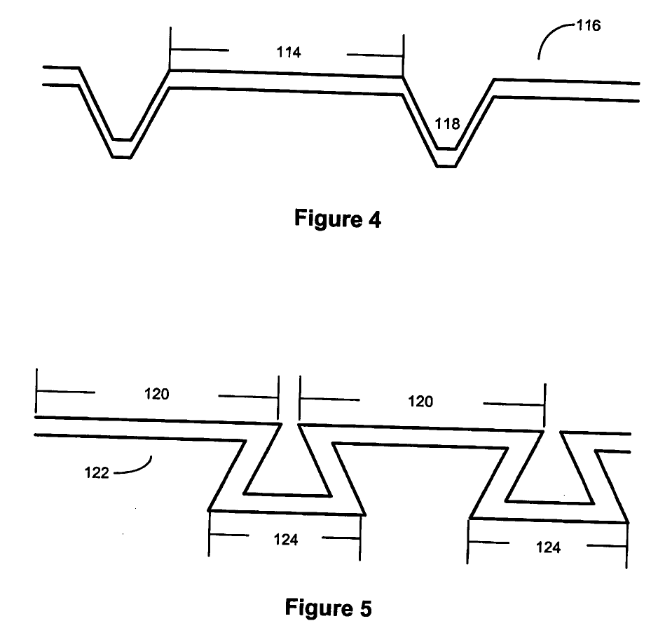

In the embodiment of an open corrugate, as shown in FIGS. 3 and 4, the solar cells 100 can be spaced on the module 112 so that only the flat portions 114 of the corrugate structure 116 have PV elements 104. The corrugations preferably remain below the cell plane to preclude shading and the associated performance and reliability issues it creates.

In other embodiments, a flexible solar sheet can be attached to the surface of a corrugate structure. The lamination of the solar sheet can be performed either before or after attachment of a corrugate structure. The corrugate structure can consist of open corrugations, as shown In FIG. 4, in which troughs 118 are left between rows of cells 100, or it can consist of closed corrugations, as shown in FIG. 5, in which the top surface 120 of the corrugate 122 becomes a continuous plane. The closed troughs 124 in the sheet can be tubular, triangular or other standard forms, where the corrugations 124 are pinched off at their top surface to create a plane. In another embodiment, a mix of open and closed corrugations can be formed in either regular or irregular shapes.

One approach of forming these corrugations is very much like a standing seam roof in which pinched-off areas of the sheet are pressed completely flat and have little cross-sectional open area, but extend below rather than above the cell plane. This embodiment will be discussed below with relation to a figure. Another variation of this approach is to simply laminate PV modules to narrow strips of metal (approx. 18-24″ wide) and roll the edges in a standard seam roof coil converter. These pieces can then be assembled together using conventional assembly hardware or other such standard means to provide a structurally rigid module having a large surface area, but again the edges are formed below rather than above the cell plane. In many of these embodiments, a frame is preferably formed at the edges of the sheet to allow for simplified installation of the modules into a structural framework. End caps may also be placed on the assembly to create a complete frame and control air flow.

Many other embodiments preferably include at least one additional sheet of material for the additional structural support. This additional support can be provided by attaching a flat solar sheet to an existing corrugate or even an extruded three-dimensional sheet. The structure preferably provides a planar face of PV cells though the face can be either interrupted, as shown with the open corrugate, or curved to fit a structured form.

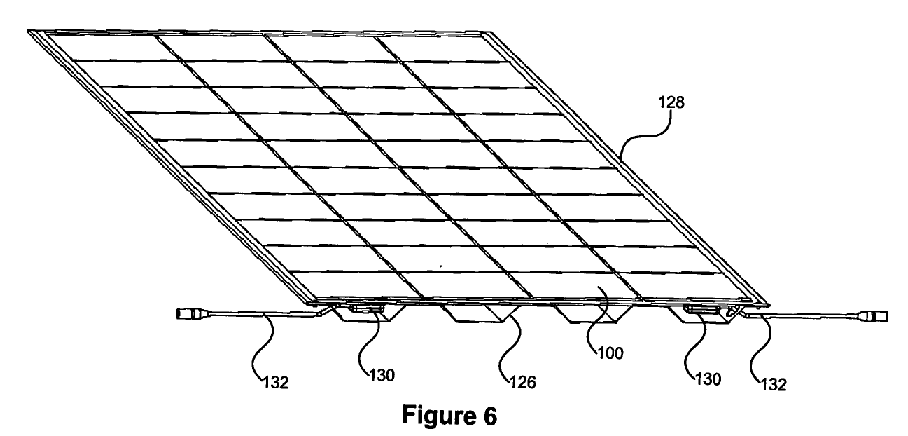

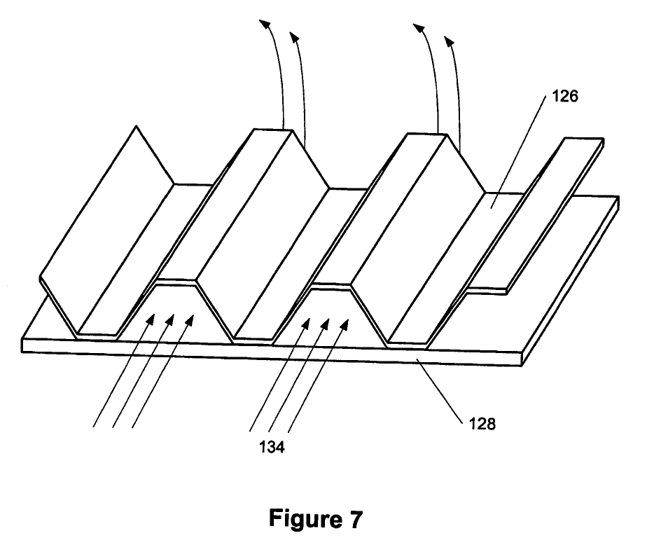

One such design, as illustrated in FIGS. 6 and 7, involves attaching a sheet of corrugated metal 126 to the back of a PV laminate 128 which has as part of its construction a metal layer and a plurality of PV cells 100. This attaching can be done using any one of, or a combination of, screws, rivets, tabs, glue, adhesive tapes, and other conventional means. This structure has excellent strength along the direction of the rolled corrugation but can be bent to conform to the curvature of a building surface in the other direction. Junction boxes 130 can be used to connect the module to other modules or to the power system. Preferably the cables 132 are quick connect cables that allow for rapid installation without requiring sophisticated installation teams. This structure allows airflow 134 to aid in the dissipation of heat as air is drawn through the corrugations.

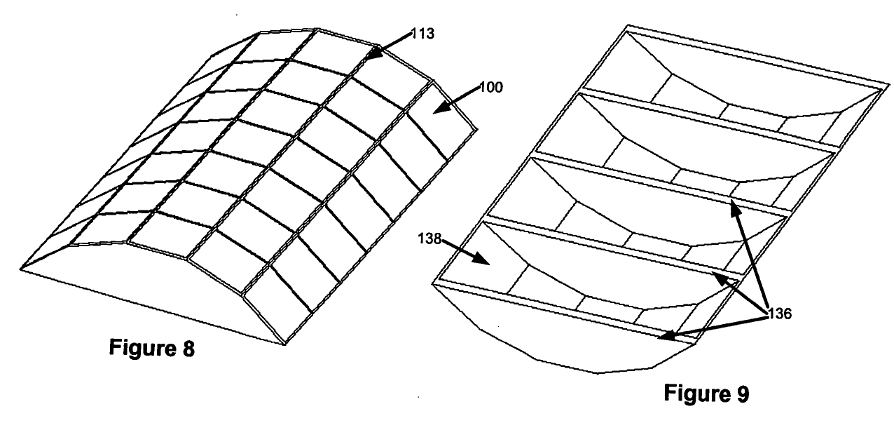

In another embodiment, a flexible sheet with a metal layer backing is curved or bent to fit with a structured form that supports the new shape. FIGS. 8 and 9 provide top and bottom perspective views of one such embodiment. A flexible PV module 113 having cells 100 is formed with a rigid back that provides both strength and rigidity. The module is then bent to take a shape, such as the illustrated curve. This bent module can be attached to structural supports 136. Supports 136 serve to further reinforce the structure and provide rigidity. The spaces 138 between supports 136, can be used to hold a junction box connected to the PV cells 100. This allows for a finished product that can be easily deployed and installed by affixing the module to the desired location using standard construction techniques, and simply connecting the junction boxes either to other modules or to a power conditioner/inverter. The structured module can be easily moved to the installation site, as it is durable, resistant to fracture, and lighter weight than a standard glass module of the equivalent size.

In another embodiment a complex corrugation pattern, similar to that used in high strength cardboard that can provide strength along both axes of the sheet is used. Some of these complex designs require more advanced rolling techniques and preferably involve providing a wave pattern, such as herringbone, in the roll direction.

One feature of the corrugated designs, of the above described figures, is that air can flow directly against the back surface of the laminate. This provides cooling to the solar sheet, which is desirable to limit cell efficiency losses caused by heating. In one embodiment, the corrugate backing is preferably perforated, or even expanded material, which allows for the maximization of airflow while minimizing the weight of the corrugate with little detriment to structural integrity.

With corrugated designs, it is presently preferable to provide a nesting feature with a recessed junction box. This design allows two modules to be nested back-to-back thus minimizing shipment volume. Additionally, with the two sheet design of FIGS. 6 and 7, the edges of the metal backed PV laminate 128 or the corrugate 126 can be rolled over the other, improving edge strength and protecting the installer from cuts.

An extruded three-dimensional sheet of material such as polypropylene or even aluminum serving as a corrugate 126 behind the PV module 128 allows for airflow 134, though it may not offer the same cooling efficiencies as the air would not be in direct contact with the backing of the module and instead makes contact with the metal layer.

In another embodiment, the PV prelaminate can be affixed to a rigid metal backing that forms the top layer of a sandwich. Two metal layers, one of which carries the PV module, can sandwich a polymer core such as polypropylene (PP) or polyethylene (PE). The end product is essentially a standard architectural product with integrated energy generating potential. After creating the PV module, grooves can be routed into the back surface of the product. By folding along the routed lines, the module can be bent to form three dimensional structures such as a frame around the perimeter of the module.

The corrugated laminates of the present invention allow for a modular design with one or two junction boxes per module. The use of quick-connect cable terminations eliminates much of the on site wiring and assembly that some of the prior art requires. As a result, the product can be treated like a standard photovoltaic module for installation. As opposed to most of the prior art, no special installation training is required, the module is simply installed using standard photovoltaic module Installation techniques.

The corrugate construction provides a strong module that is both light weight and cost effective. In comparison to glass modules, the modules of the present invention avoid increased weight per watt of generating capacity, as thicker corrugate or thicker superstrates are not required as the module size increases. Additionally, the installation is simplified as the modules are more robust and are not prone to shattering if another object impacts the module surface. The inclusion of the corrugate sufficiently strengthens the module so that it is as strong as conventional glass modules. In comparison to prior art systems employing flexible modules, the modules of the present invention are consistently rigid and do not have unsupported areas that cannot bear a load. Additionally, the modular nature of the present invention avoids the prior art problem of requiring a specially trained installation crew, or requiring on-site module assembly. This reduces the installation costs and allows quality control to be exercised by the manufacturer. Assembly in a controlled environment is not possible with the prior art systems that require interconnected elements or provide the solar modules separately from the structural elements.

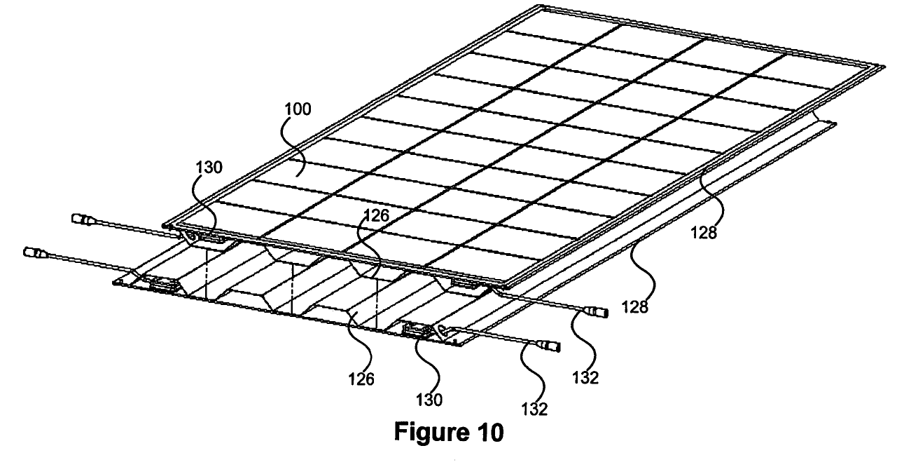

FIG. 10 illustrates a the nesting of modules so that cells 100 face opposite directions, and the corrugated sections of backing 126 nest within each other. Junction boxes 130 by being in one of the covered troughs do not interfere with the nesting of the modules. This allows for a smaller shipping volume to an installation site.

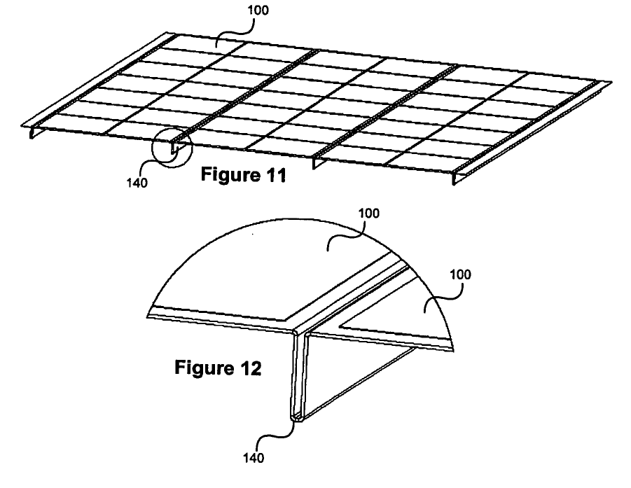

FIGS. 11 and 12 illustrate a solar module constructed to form standing seams. Whereas many prior art implementations are directed to affixing solar cells to a standing seam, the embodiment illustrated in FIG. 11 has cells 100 spaced apart from each other, with a gap at fixed intervals. These gaps are folded into standing seams 140 that both increase the strength of the module, and raise the portions of the module bearing solar cells 100. By raising cells 100, seams 140 allow airflow under the module and provide a location for placing junction boxes and other such connectors. One skilled in the art will appreciate that the standing seam modules can also be nested, although the location of junction boxes will determine the orientation of the panels when nested back to back. This nesting allows for tighter packing In transit and a reduction in the shipping volume of the module. FIG. 12 illustrates the encircled detail of FIG. 11 and clearly shows the placement of cells 100 with respect to seam 140.

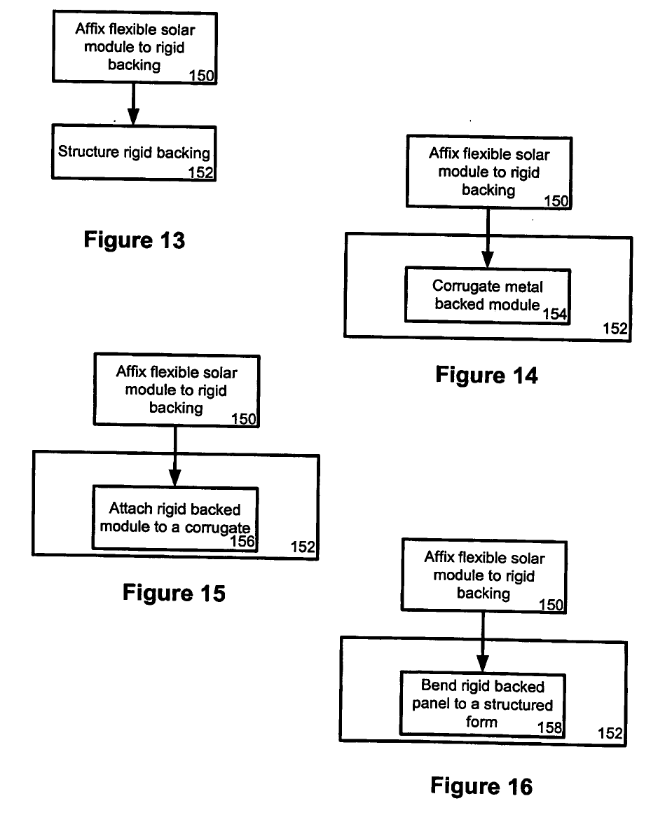

One skilled in the art will appreciate that there are many ways that the structured modules of the present invention can be manufactured. One such method will now be discussed with relation to the flowchart of FIG. 13. In step 150 a flexible solar module is affixed to a metal backing. In the interests of reducing the mass of the module it is preferable to use a low density and strong metal such as aluminum. In addition to providing rigidity, the metal backing can serve as a heat sink to aid in the dissipation of heat buildup caused during the operation of the module. The flexible solar module can be attached to the metal backing in a number of ways including the use of a fastener, an adhesive, or the metal backing can be affixed by including the metal backing in the laminating process. It is preferable, though not required, that the module be integral with the backing, so that no folds or distortions occur later in the process.

In step 152, the metal backing is structured to allow for greater strength and rigidity. This results in a module that has a rigid backing and a structure. The structure of the module provides strength, in at least one direction, and allows the module to serve as a replacement for conventional glass modules at lower cost and weight.

FIG. 14 illustrates an embodiment of the above method, where the step of structuring the metal backing is performed by corrugating the metal backing in step 154. In this embodiment of the method, it is preferable that the flexible solar module is affixed to the rigid backing in step 150 with spaces between cells to allow for the corrugations.

FIG. 15 illustrates a further embodiment, where the step of structuring in step 152 includes attaching the rigid backed module to a corrugate in step 156. The attaching of the rigid module is preferably done by gluing, spot welding, or fastening the rigid backed module to the corrugate. In one embodiment, the edges of the corrugate are folded over the edges of the rigid backed module to strengthen the edges of the product. In other embodiments, the edges of the module are bent back to fold over the edges of the corrugate, or end caps are used to clamp the corrugate and the module together. End caps may be added to strengthen ends of the module and/or to control air flow.

FIG. 16 illustrates a further embodiment of the present invention, where the rigid backed module is bent to a structured form in step 158, as described above in conjunction with FIGS. 8 and 9 or FIGS. 11 and 12. The rigid backed module is preferably bent to a structural form in step 158 and then secured to a frame that provides additional support and structure.

The above-described embodiments of the present invention are intended to be examples only. Alterations, modifications and variations may be effected to the particular embodiments by those of skill in the art without departing from the scope of the invention, which is defined solely by the claims appended hereto.

1. A rigid solar module having a flexible solar module prelaminate, the module comprising:
a metal backing affixed to the prelaminate;
a corrugated backing affixed to the metal backing for providing rigidity to the combination of the metal backing and the prelaminate; and
a junction box providing a connection to the prelaminate, for transferring power to a load.

2. The module of claim 1 wherein the metal backing is laminated to the prelaminate.

3. The module of claim 2 wherein the edges of the metal backing are folded over the edges of the corrugate backing to affix the corrugate backing to the metal backing.

4. The module of claim 1 further including a flexible backing interposed between the metal backing and the prelaminate in a laminate.

5. The module of claim 1 wherein the corrugated backing and the metal backing are integral.

6. The module of claim 1 wherein edges of the corrugated backing are folded over the edges of the prelaminate to affix the corrugated backing to the metal backing.

7. The module of claim 1 wherein the junction box is positioned inside a trough in the corrugate.

8. A method of forming a rigid photovoltaic module from a flexible photovoltaic module, the method comprising:
affixing the flexible photovoltaic module to a rigid backing; and
structuring the rigid backed photovoltaic module to provide increased strength in at least one direction.

9. The method of claim 8 wherein the rigid backing is a metal backing.

10. The method of claim 9 wherein the metal is aluminum.

11. The method of claim 8, wherein the step of affixing includes gluing the flexible module to the backing.

12. The method of claim 8, wherein the step of affixing includes laminating the flexible photovoltaic module to the rigid backing.

13. The method of claim 8, wherein the step of affixing the flexible photovoltaic module to the rigid backing includes integrally affixing the module to the backing.

14. The method of claim 8, wherein the step of structuring the metal backing includes bending the rigid backed photovoltaic module to create a curve.

15. The method of claim 14 further including the step of adding supports in a hollow portion of the curve.

16. The method of claim 15 further including the step of connecting a junction box to the photovoltaic module and locating the junction box between supports in the hollow portion of the curve.

17. The method of claim 8 wherein the step of structuring the metal backing includes corrugating the rigid backed photovoltaic module and affixing a junction box under a flat section of the corrugated rigid backed photovoltaic module.

18. The method of claim 8 wherein the step of structuring includes affixing the rigid backed photovoltaic module to a corrugate.

19. The method of claim 18 wherein the step of affixing the rigid backed photovoltaic module to the corrugate includes folding the edges of one of the corrugate and the photovoltaic module over the edges of the other one of the corrugate and the photovoltaic module.

20. The method of claim 18 further including the step of connecting a junction box to the photovoltaic module and locating the junction box in a trough of the corrugate.

21. The method of claim 8, wherein the step of structuring the metal backing includes bending the rigid backed photovoltaic module to create standing seams beneath the plane of the flexible photovoltaic module.

22. The method of claim 21 further including the step of connecting a junction box to the photovoltaic module and locating the junction box between two of the standing seams.
